(19) United States
(12) Patent Application Publication
(10) Pub. No.: US 2014/0335288 A1
(43) Pub. Date: Nov. 13, 2014

(54) PLASMA PROCESSING DEVICE AND PLASMA PROCESSING METHOD

(71) Applicant: Masaki Hirayama, Sendai-shi (JP)

(72) Inventor: Masaki Hirayama, Sendai-shi (JP)

(73) Assignee: Tohoku University, Sendai-shi, Miyagi (JP)

(21) Appl. No.: 14/370,299

(22) PCT Filed: Feb. 24, 2012
(86) PCT No.: PCT/JP2012/001304

§ 371 Date: Jul. 2, 2014

(51) Int. Cl. H01J 37/32

(52) U.S. Cl. CPC H01J 37/32568; H01J 37/32229; H01J 37/32577; H01J 2237/3326; H01J 2237/3321
USPC 427/569; 118/723 R

(57) ABSTRACT

There is provided a plasma processing apparatus which can improve density uniformity of plasma excited by a high frequency wave as in the VHF frequency band and reduce production costs by downsizing for a substrate having a large size. The plasma processing apparatus includes a waveguide member defining a waveguide, first and second electrodes disposed so as to face a plasma formation space, defining the waveguide in cooperation with the waveguide member, and electrically connected to the waveguide member; a coaxial tube supplying electromagnetic energy into the waveguide; a dielectric plate disposed in the waveguide and extending in a longitudinal direction; and first and second conductors disposed, in the waveguide, on at least one side of the waveguide in a width direction with respect to the dielectric plate, extending along the dielectric plate, and electrically connected to the first and second electrodes.

### TECHNICAL FIELD

The present invention relates to a plasma processing apparatus and a plasma processing method which perform plasma processing on a substrate.

### BACKGROUND ART

In the manufacturing processes of a flat-plate display, as solar battery, a semiconductor device, and the like, plasma is used for thin film formation, etching, and the like. For example, plasma is generated by means of introducing gas into a vacuum chamber and applying a high frequency wave of several MHz to several hundred MHz to an electrode provided in the chamber. For improving productivity, a glass-substrate size of the flat-plate display or the solar battery is increased year by year, and volume production of a glass substrate having a size larger than 2 m square has already being carried out.

In a film deposition process such as plasma CVD (Chemical Vapor Deposition), plasma having a higher density is required for improving a film deposition rate. Further, plasma having a lower electron temperature is required for suppressing the energy of an ion entering a substrate surface to reduce ion irradiation damage and also for suppressing excessive disassociation of a gas molecule. Generally, when a plasma excitation frequency is increased, the plasma density is increased and the electron temperature is reduced. Accordingly, for depositing a high quality thin film at a high throughput, it is necessary to increase the plasma excitation frequency. Therefore, for the plasma processing, a high frequency wave in the VHF (Very High Frequency) band of 30 to 300 MHz, which is higher than 13.56 MHz of a frequency for a typical high-frequency power source, has been used (refer to Patent Literatures 1 and 2, for example).

### CITATION LIST

### Patent Literature

PTL 1: Japanese Patent Laid-Open No. H09-312268 (1997)

PTL 2: Japanese Patent Laid-Open No. 2009-021256

### SUMMARY OF INVENTION

### Technical Problem

Meanwhile, when the size of a glass substrate to be processed becomes as large as 2 m square, for example, and is plasma-processed at a plasma excitation frequency of the VHF band as described above, uniformity of the plasma density is degraded because of a standing wave of a surface wave caused in an electrode to which the high frequency wave is applied. Generally, when the electrode to which the high frequency wave is applied has a size larger than 1/20 of a free space wavelength, it is impossible to excite uniform plasma without any countermeasure.

The present invention provides a plasma processing apparatus which can improve the density uniformity of the plasma excited by a high frequency wave as in the VHF frequency band for a larger substrate having a size larger than 2 m square.

### Solution to Problem

A plasma processing apparatus of the present invention includes a waveguide member defining a waveguide having a rectangular cross section in a direction crossing a longitudinal direction; first and second electrodes for electric field formation disposed so as to face a plasma formation space, defining the waveguide in cooperation with the waveguide member, and electrically connected to the waveguide member; a transmission path supplying electromagnetic energy from a predetermined power supply position in the longitudinal direction into the waveguide; a dielectric plate disposed in the waveguide and extending in the longitudinal direction; and at least one conductor disposed, in the waveguide, on at least one side of the waveguide in a width direction with respect to the dielectric plate, extending along the dielectric plate, and electrically connected to one of the first and second electrodes.

### Advantageous Effects of Invention

According to the present invention, it is possible to improve density uniformity of plasma excited in the VHF frequency band in the longitudinal direction of the waveguide for a larger object (substrate) to be processed. According to the present invention, it is also possible to downsize the apparatus and reduce production costs.

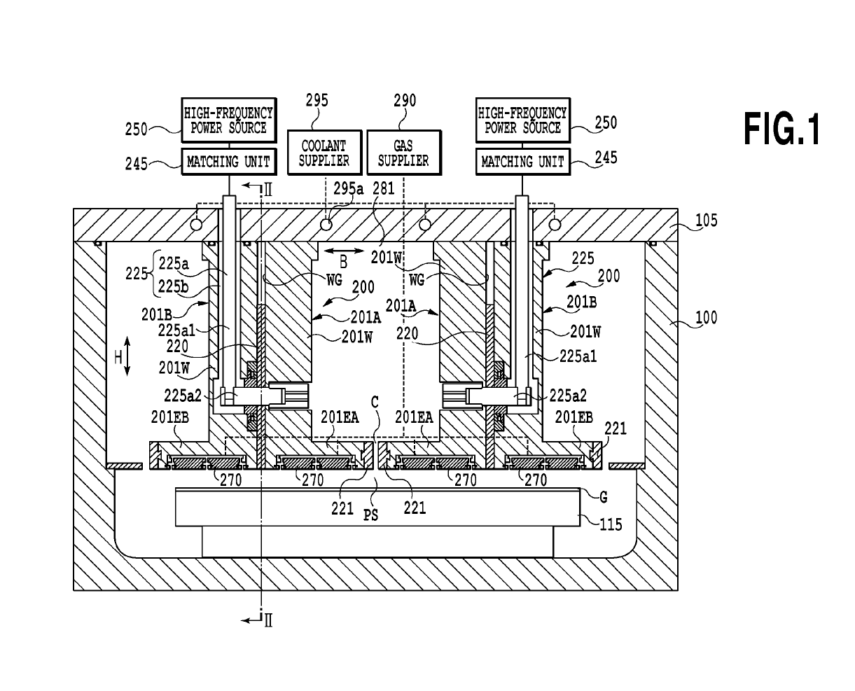

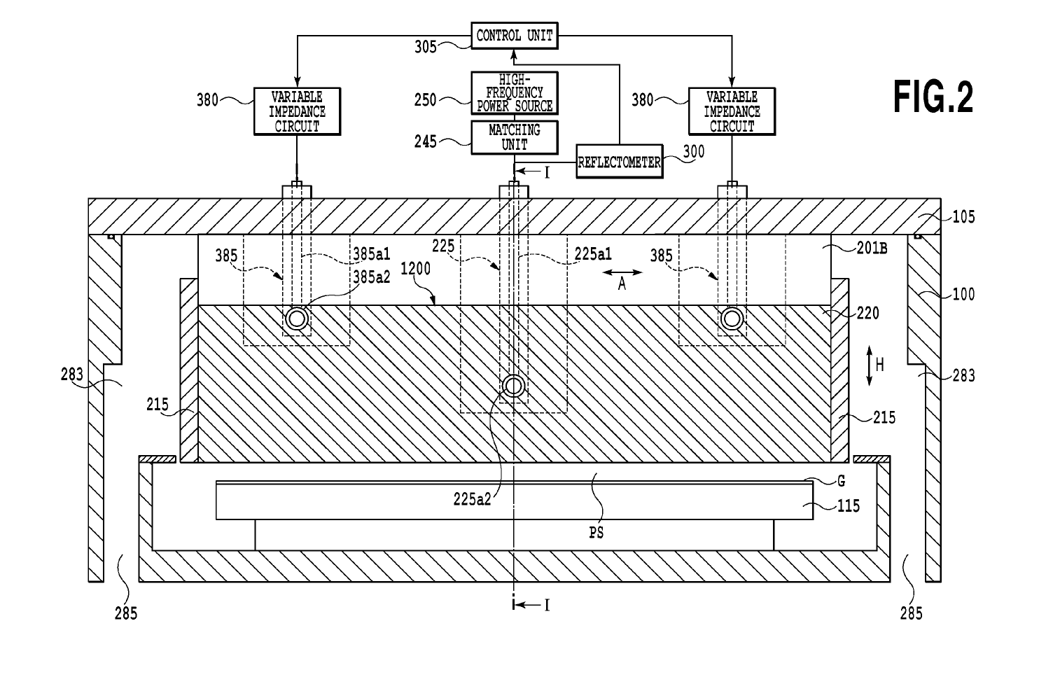

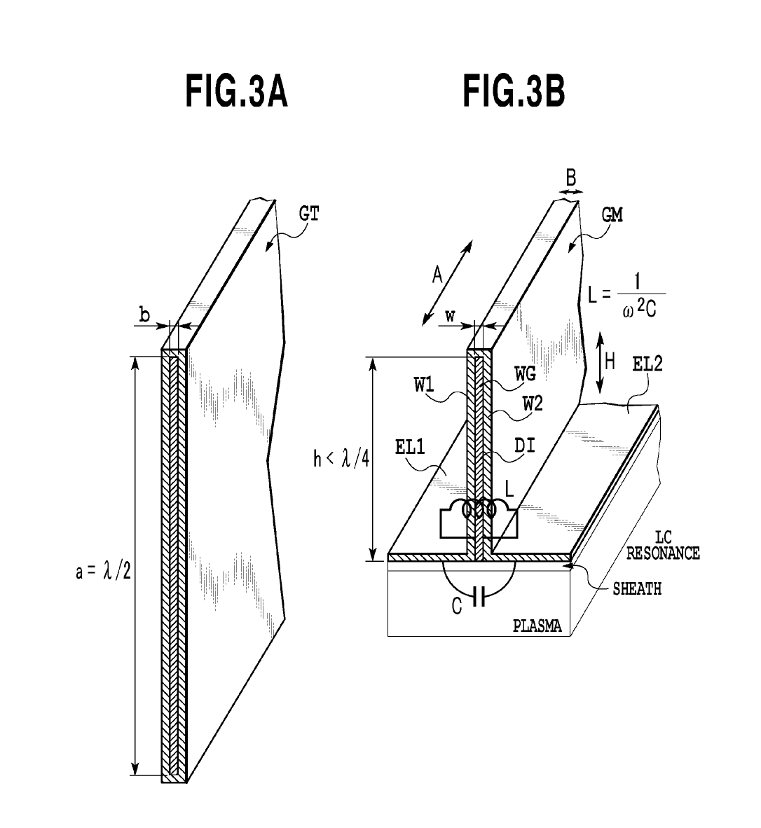

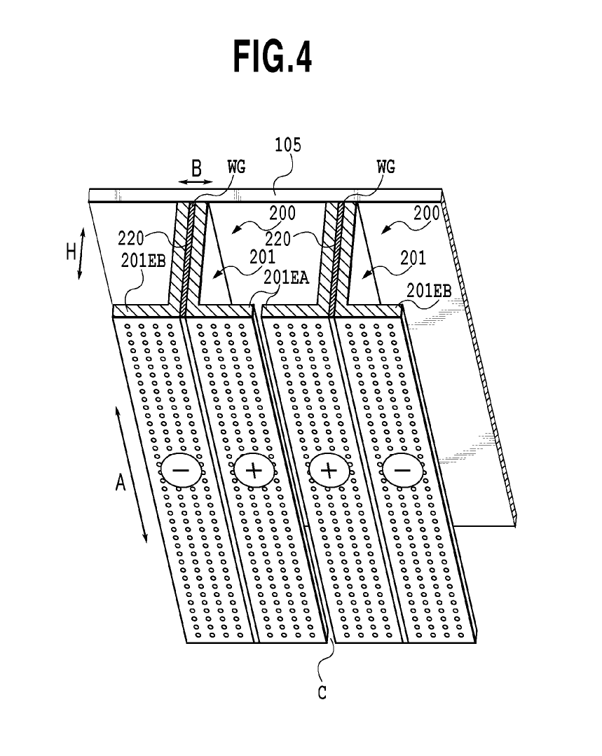

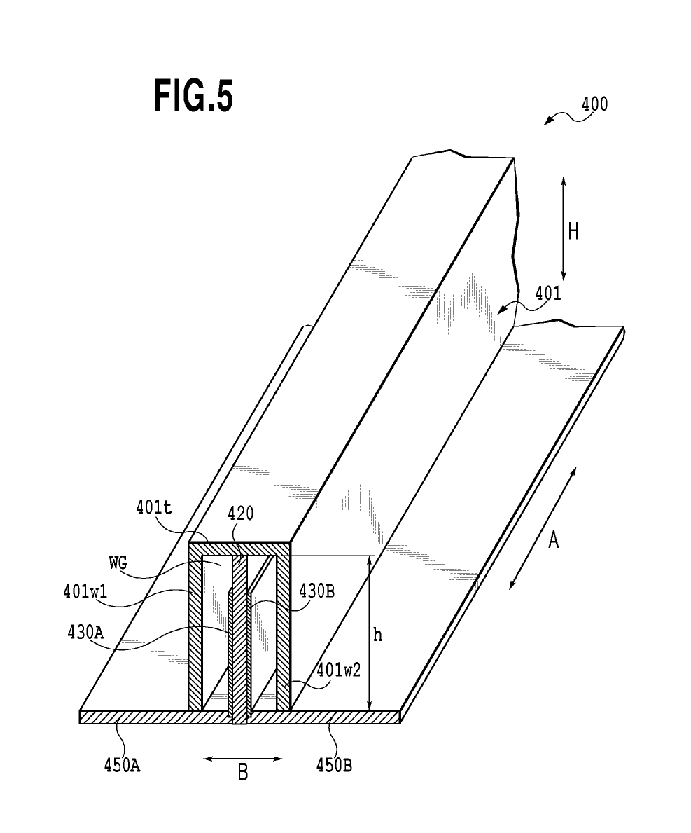

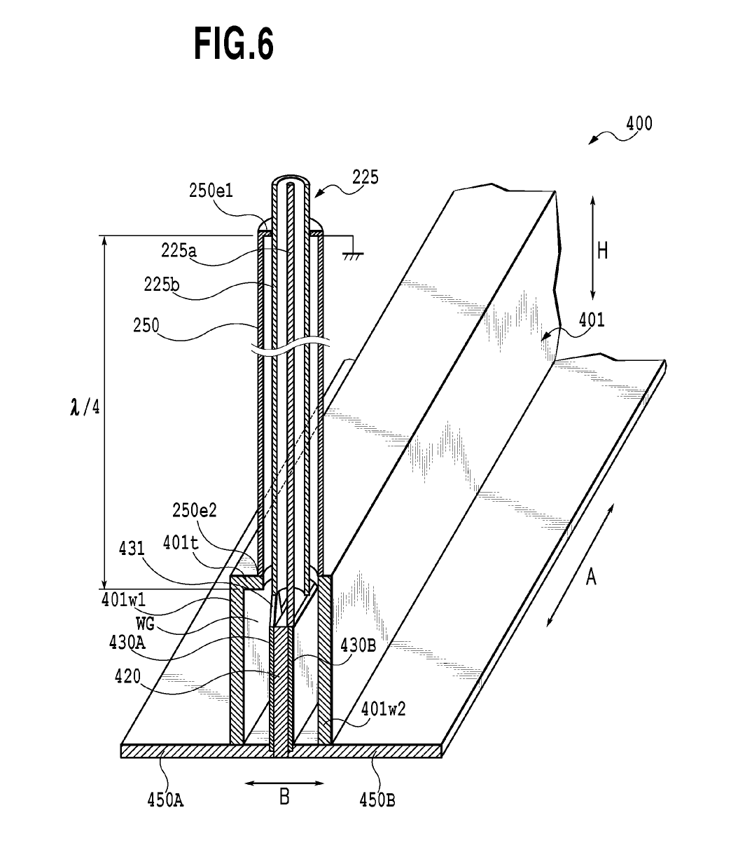

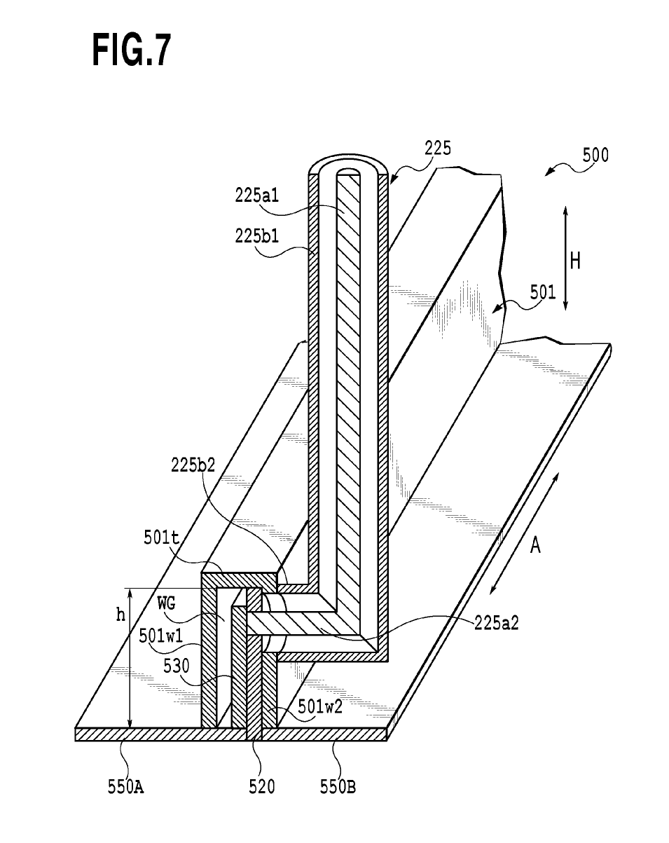

### BRIEF DESCRIPTION OF DRAWINGS

[FIG. 1] FIG. 1 is a cross-sectional view showing an example of a plasma processing apparatus;

[FIG. 2] FIG. 2 is a II-II cross-sectional view of the plasma processing apparatus of FIG. 1;

[FIG. 3A] FIG. 3A is a perspective cross-sectional view showing a waveguide tube in a cut-off state;

[FIG. 3B] FIG. 3B is a perspective cross-sectional view of a waveguide having an equivalent relationship with the waveguide tube of FIG. 3A;

[FIG. 4] FIG. 4 is a perspective cross-sectional view showing a structure of a basic-type plasma generation mechanism in the plasma processing apparatus of FIG. 1;

[FIG. 5] FIG. 5 is a perspective cross-sectional view showing a structure of a plasma generation mechanism according to a first embodiment of the present invention;

[FIG. 6] FIG. 6 is a cross-sectional perspective view showing a connection relation between a waveguide and a coaxial tube of FIG. 5; and

[FIG. 7] FIG. 7 is a perspective cross-sectional view showing a structure of a plasma generation mechanism according to a second embodiment of the present invention.

### DESCRIPTION OF EMBODIMENTS

Hereinafter, embodiments of the present invention will be explained in detail with reference to the attached drawings. Note that, in the present specification and the drawings, the same reference numeral is given to a constituent element having substantially the same functional configuration, so that repeated explanation will be omitted.

### Basic Configuration of a Plasma Processing Apparatus

First, an example of a plasma processing apparatus of a type to which the present invention is applied will be explained with reference to FIG. 1 and FIG. 2. FIG. 1 is a I-I cross-sectional view of FIG. 2, and FIG. 2 is a II-II cross-sectional view of FIG. 1. A plasma processing apparatus 10 shown in FIG. 1 and FIG. 2 has a configuration in which electromagnetic energy is supplied to an electrode by the use of a waveguide which is designed so as to cause a supplied electromagnetic wave to resonate and thereby plasma having uniform density in the longitudinal direction of the waveguide can be excited.

Here, resonance in a waveguide will be explained. First, as shown in FIG. 3A, an in-tube wavelength in a rectangular waveguide tube GT having a cross section with a long side length of a and a short side length of b is considered. An in-tube wavelength λg is expressed by the following formula (1).

$$\begin{matrix}[ Formula 1 ] & \\ {λ}_{g} = \frac{λ}{\sqrt{{ɛ}_{r} {μ}_{r}} \sqrt{1 - λ / 2 a}} & ( 1 )\end{matrix}$$

Here, λ is a free space wavelength, εr is a relative permittivity in the waveguide tube, and pr is a relative permeability in the waveguide tube. According to formula (1), for εr=μr=1, it is found that the in-tube wavelength λg in the waveguide tube GT is always longer than the free space wavelength λ. For λ<2a, the in-tube wavelength λg becomes longer as the long side length a becomes smaller. For λ=2a, that is, when the long side length a is equal to ½ of the free space wavelength λ, the denominator becomes zero and the in-tube wavelength λg takes an infinite value. At this time, the waveguide tube GT becomes a cut-off state and phase velocity of an electromagnetic wave propagating in the waveguide tube GT takes an infinite value and group velocity becomes zero. Further, for λ>2a, the electromagnetic wave cannot propagate in the waveguide tube, while the electromagnetic wave can enter the waveguide tube to some extent. Note that, while generally this state is also called the cut-off state, here the state for λ=2a is called the cut-off state. For example, at a plasma excitation frequency of 60 MHz, a becomes 250 cm for a hollow waveguide tube and 81 cm for an alumina waveguide tube.

FIG. 3B shows a basic type waveguide used for the plasma processing apparatus 10. A waveguide member GM defining this waveguide WG is formed of a conductive member, and includes side wall parts W1 and W2 which extend in the waveguide direction (longitudinal direction) A and face each other in the width direction B, and first and second electrode parts EL1 and EL2 which extend in flange shapes in the lower end parts in the height direction H of the side wall parts W1 and W2. Further, a dielectric DI in a plate shape is inserted in a gap formed between the side wall parts W1 and W2. This dielectric DI plays a role of preventing plasma excitation in the waveguide WG. A width w of the waveguide WG shown in FIG. 3B is set to a value equal to the short side length b of the waveguide, and a height h is set to an optimum value smaller than λ/4 (a/2) so as to be electrically equivalent to the waveguide tube GT in the cut-off state. In the waveguide WG, an LC resonance circuit is formed by I (inductance) and C (capacitance) to become the cut-off state, and thereby a supplied electromagnetic wave resonates. When the wavelength of a high frequency wave propagating in the waveguide WG in the waveguide direction A reaches an infinite value, a high-frequency electric field is formed uniformly in the longitudinal direction of the electrodes EL1 and EL2 and plasma is excited having uniform density in the longitudinal direction. Here, if an impedance when viewed from the waveguide WG to the plasma side is assumed to have an infinite value, the waveguide WG can be assumed to be a transmission path which is formed by dividing a rectangular waveguide tube just in half in the long side direction. Therefore, when the height h of the waveguide WG is λ/4, the in-tube wavelength λg takes an infinite value. However, since actually the impedance when viewed from the waveguide WG to the plasma side is capacitive, the height h of the waveguide WG causing the in-tube wavelength λg to take the infinite value is smaller than λ/4.

The plasma processing apparatus 10 includes a vacuum container 100 mounting a substrate G therein, and applies plasma processing to a glass substrate (hereinafter, referred to as a substrate G) therein. The vacuum container 100 has a rectangular cross section, is formed of metal such as an aluminum alloy, and is earthed. An upper opening of the vacuum container 100 is covered by a ceiling part 105. The substrate G is mounted on a mounting stage 115. Note that the substrate G is an example of an object to be processed, and the object to be processed is not limited to this and may be a silicon wafer of the like.

On a floor part of the vacuum container 100, the mounting stage 115 is provided for mounting the substrate G. Above the mounting state 115, plural (two) plasma generation mechanisms 200 are provided via a plasma formation space PS. The plasma generation mechanism 200 is fixed to the ceiling part 105 of the vacuum container 100.

Each of the plasma generation mechanisms 200 includes two waveguide members 201A and 201B which are formed of an aluminum alloy and have the same size, a coaxial tube 225, and a dielectric plate 220 inserted in the waveguide WG formed between the two facing waveguide members 201A and 201B.

The waveguide members 201A and 201B include flat plate parts 201W which face each other with a predetermined gap for forming the waveguide WG and electrode parts 201EA and 201EB for electric field formation which are formed in flange shapes at the lower end parts of these flat plate parts 201W to excite plasma, respectively. The upper end parts of the waveguide members 201A and 201B are connected to the ceiling part 105 formed of conductive material and the upper end parts of the waveguide members 201A and 201B are electrically connected with each other.

The dielectric plate 220 is formed of dielectric material such as aluminum oxide or quartz and extends upward from the lower end of the waveguide WG to a midpoint of the waveguide WG. Since the upper part of the waveguide WG is short-circuited, an electric field is weaker on the upper side than on the lower side in the waveguide WG. Therefore, when the lower side of the waveguide WG where the electric field is strong is blocked up with the dielectric plate 220, the upper part of the waveguide WG may be hollow. Obviously, the waveguide WG may be filled with the dielectric plate 220 up to the upper part.

The coaxial tube 225 is connected to an approximately center position in the longitudinal direction A of the waveguide WG as shown in FIG. 2 and this position becomes a power supply position. An outer conductor 225b of the coaxial tube 225 is configured with a part of the waveguide member 201B, and an inner conductor 225a1 passes through the center part of the outer conductor 225b. The lower end part of the inner conductor 225a1 is electrically connected to an inner conductor 225a1 which is disposed perpendicularly to the inner conductor 225a1. The inner conductor 225a2 passes through a hole opened in the dielectric plate 220 and is electrically connected to the electrode part 201EA on the side of the waveguide member 201A.

The inner conductors 225a1 and 225a2 of the coaxial tube 225 are electrically connected to the one electrode part 201EA in the plasma generation mechanism 200, and the outer conductor 225b of the coaxial tube 225 is electrically connected to the other electrode part 201EB in the plasma generation mechanism 200. To the upper end of the coaxial tube 225, a high-frequency power source 250 is connected via a matching box 245. High-frequency power supplied from the high-frequency power source 250 propagates via the coaxial tube 225 from the center position in the longitudinal direction A toward both end parts of the waveguide WG.

The inner conductor 225a2 passes through the dielectric plate 220. The inner conductors 225a2 provided in the respective adjacent plasma generation mechanisms 200 pass through the respective dielectric plates 220 of the plasma generation mechanisms 200 in directions opposite to each other. Here, when the high frequency waves having the same amplitude and the same phase are supplied to the coaxial tubes 225 of the two plasma generation mechanisms 200, respectively, high frequency waves having the same amplitude and opposite phases are applied to the electrode parts 201EA and 201EB in the two plasma generation mechanisms 200, respectively, as shown in FIG. 4. Here, in the present specification, a high frequency wave means a wave in a frequency band of 10 MHz to 3,000 MHz and is an example of an electromagnetic wave. Further, the coaxial tube 225 is an example of a transmission path supplying the high frequency wave, and a coaxial cable, a rectangular waveguide tube, or the like may be used instead of the coaxial tube 225.

As shown in FIG. 1, for preventing discharge on the side faces of the electrode parts 201EA and 201EB and for preventing entry of plasma into the upper part, the side faces of the electrode parts 201EA and 201EB in the width direction B are covered with first dielectric covers 221. As shown in FIG. 2, for causing the end face of the waveguide WG in the longitudinal direction A to have an open state and also for preventing discharge on both of the side faces, both side faces of the flat plate parts 201W in the longitudinal direction A are covered with second dielectric covers 215.

While the lower face of the electrode parts 201EA and 201EB are formed so as to be approximately flush with the lower end face of the dielectric plate 220, the lower end face of the dielectric plate 220 may protrude or recede from the lower faces of the electrode parts 201EA and 201EB. The electrode parts 201EA and 201EB double as shower plates. Specifically, concave parts are formed on the lower faces of the electrode parts 201EA and 201EB and electrode caps 270 for the shower plates are fit in these concave parts. A plurality of gas ejection holes are provided in the electrode cap 270, and gas having passed through a gas flow path is ejected from these gas ejection holes to the side of the substrate G. A gas nozzle made of an electrical insulator such as aluminum oxide is provided at the lower end of the gas flow path (refer to FIG. 1).

For performing uniform process, it is not sufficient only to realize the uniform plasma density. Gas pressure, source gas density, reaction-produced gas density, gas residence time, substrate temperature, and the like affect the process and therefore these factors are required to be uniform on the substrate G. In a typical plasma processing apparatus, a shower plate is provided at a part facing the substrate G and gas is supplied toward the substrate. The gas is configured to flow from the center part of the substrate G toward the outer peripheral part and to be exhausted from the periphery of the substrate. Naturally, pressure is higher in the center part than in the outer peripheral part on the substrate and the residence time is longer in the outer peripheral part than in the center part on the substrate. When the substrate size is increased, it is difficult to perform the uniform process because of the uniformity degradation of these pressure and residence time. For performing the uniform process also on a large area substrate, it is necessary to perform gas supply from directly above the substrate G and to perform exhaustion from directly above the substrate at the same time.

In the plasma processing apparatus 10, an exhaustion slit C is provided between the adjacent plasma generation mechanisms 200. That is, gas output from a gas supplier 290 is supplied to the processing chamber from the lower face of the plasma generation mechanism 200 through the gas flow path formed in the plasma generation mechanism 200, and exhausted to the upper direction from the exhaustion slit C provided directly above the substrate G. The gas having passed through the exhaustion slit C flows in a first exhaustion path 281 which is formed above the exhaustion slit C by the adjacent plasma generation mechanisms 200, and guided to a second exhaustion path 283 which is provided between the second dielectric cover 215 and the vacuum container 100. Further, the gas flows downward in a third exhaustion path 285 which is provided on the side wall of the vacuum container 100 and exhausted by a vacuum pump (not shown in the drawing) which is provided below the third exhaustion path 285.

A coolant flow path 295a is formed in the ceiling part 105. Coolant output from a coolant supplier 295 flows in the coolant flow path 295a, and thereby heat flowing from the plasma is configured to be conducted to the side of the ceiling part 105 via the plasma generation mechanism 200.

In the plasma processing apparatus 10, an impedance variable circuit 380 is provided for electrically changing the effective height h of the waveguide WG. Other than the coaxial tube 225 which supplies the high frequency wave and is provided at the center part in the electrode longitudinal direction, two coaxial tubes 385 are provided in the vicinities of both ends in the electrode longitudinal direction for respectively connecting the two impedance variable circuits 380. For not disturbing the gas flow in the first gas exhaustion path 281, an inner conductor 385a2 of the coaxial tube 385 is provided above the inner conductor 225a2 of the coaxial tube 225.

As a configuration example of the impedance variable circuit 380, there would be a configuration of using only a variable capacitor, a configuration of connecting a variable capacitor and a coil in parallel, a configuration of connecting a variable capacitor and a coil in series, and the like.

In the plasma processing apparatus 10, when the state becomes the cut-off state, the effective height of the waveguide WG is adjusted so as to cause reflection viewed from the coaxial tube 225 to have the smallest value. Further, preferably the effective height of the waveguide is adjusted also during the process. Therefore, in the plasma processing apparatus 10, a reflection meter 300 is attached between the matching box 245 and the coaxial tube 225 and a reflection state viewed from the coaxial tube 225 is configured to be monitored. A detection value by the reflection meter 300 is transmitted to a control section 305. The control section 305 provides an instruction of adjusting the impedance variable circuit 380 according to the detection value. Thereby, the effective height of the waveguide WG is adjusted and the reflection viewed from the coaxial tube 225 is minimized. Note that, since a reflection coefficient can be suppressed to a very small value by the above control, the matching box 245 can be omitted from installation.

When high frequency waves having opposite phases are supplied to the two adjacent plasma generation mechanisms 200, as shown in FIG. 4, high frequency waves having the same phase are applied to the two adjacent electrode parts 201EA and 201EA. In this state, the high frequency electric field is not applied to the exhaustion slit C between the plasma generation mechanism 200 and plasma is not generated in this part. For not causing an electric field in the exhaustion slit C, the phases of the high frequency waves propagating in the respective waveguides WG of the adjacent plasma generation mechanisms 200 are shifted by 180 degrees from each other so as to cause high frequency electric fields to be applied in opposite directions.

As shown in FIG. 1, the inner conductor 225a2 of the coaxial tube disposed in the left-side plasma generation mechanism 200 and the inner conductor 225a2 of the coaxial tube disposed in the right-side plasma generation mechanism 200 are disposed in opposite directions. Thereby, the high frequency waves having the same phase which are supplied from the high-frequency power source 250 come to have opposite phases when transmitted to the waveguide WG via the coaxial tubes.

Note that, when the inner conductors 225a2 are disposed in the same direction, by applying high frequency waves having opposite phases to each of the pair of adjacent electrodes from the high-frequency power source 250, it is possible to cause high-frequency electric fields formed on the lower faces of all the electrode parts 201EA and 201EB in the plasma generation mechanisms 200 to have the same direction and to cause the high-frequency electric field in the exhaustion slit C to be zero.

### First Embodiment

In the plasma processing apparatus 200 having the above-described configuration, by causing the waveguide WG to become the cut-off state, it is possible to excite uniform plasma on an electrode having a length equal to or larger than 2 m, for example. However, to cause the waveguide WG to become the cut-off state, when the plasma excitation frequency is 60 MHz, for example, the height h of the waveguide WG is required to be about 380 mm, and as a result, the waveguide member 201 is configured to have a size equal to or greater than 2000 mm in the longitudinal direction A and about 400 nm in the height direction H. Accordingly, the production costs of the apparatus increase and the size of the apparatus including the vacuum container 100 significantly increases. In the present embodiment, a description will be given of a plasma generation apparatus capable of suppressing the production costs by downsizing, while exciting uniform plasma on the electrode having a length equal to or greater than 2 m.

FIG. 5 is a perspective cross-sectional view of a plasma generation mechanism 400 according to the present embodiment. FIG. 6 is a cross-sectional perspective view showing a connection relation between a waveguide and a coaxial tube in the plasma generation mechanism 400 of FIG. 5. Here, the plasma generation mechanism 400 corresponds to each of the two plasma generation mechanisms 200 shown in FIG. 1 and FIG. 4. That is, the plasma processing apparatus according to the present embodiment replaces each of the two plasma generation mechanisms 200 shown in FIG. 1 and FIG. 4 with the plasma generation mechanism 400 shown in FIG. 5. In the plasma processing apparatus according to the present embodiment, there is provided an adjustment mechanism for causing the waveguide to be always in the cut-off state even when a load is changed, that is, the above-described two impedance variable circuits 380 and two coaxial tubes 385 respectively connecting the two impedance variable circuits 380. The plasma processing mechanism 400 shown in FIG. 5 is substantially equal to the above-described plasma processing mechanisms 200 and has the same functions.

The plasma processing mechanism 400 has a waveguide member 401. The waveguide member 401 is formed of conductive material such as an aluminum alloy, in a tubular shape in the longitudinal direction A, and defines the waveguide WG having a rectangular cross section in a direction crossing the longitudinal direction A. More specifically, the waveguide member 401 has an upper wall part 401t, and side wall parts 401w1 and 401w2 which extend downward from end parts of the upper wall part 401t in the width direction B.

Below the waveguide member 401, there are provided first and second electrodes 450A and 450B. The first and second electrodes 450A and 450B are plate members made of conductive material such as an aluminum alloy, have a rectangular shape, and extend in the longitudinal direction A. The first electrode 450A is disposed so as to face the plasma formation space PS and to be vertical to the side wall part 401w1, extends in the longitudinal direction A, and is electrically connected to the lower end part of the side wall part 401w1. The first electrode 450A is disposed so as to face the plasma formation space PS and to be vertical to the side wall part 401w1, extends in the longitudinal direction A, and is electrically connected to the lower end part of the side wall part 401w1. The second electrode 450B is juxtaposed with the first electrode 450A with a predetermined gap, disposed so as to face the plasma formation space PS and to be vertical to the side wall part 401w2, and electrically connected to the lower end part or the side wall part 401w2.

In the waveguide WG, there is provided a dielectric plate 420 formed of dielectric material such as aluminum oxide. The dielectric plate 420 has a rectangular shape and extends in the longitudinal direction A. The dielectric plate 420 is disposed so as to be substantially parallel to the side wall parts 401w and 401w2 at an approximately center position of the waveguide WG in the width direction B. The upper end part of the dielectric plate 420 in the height direction H is in contact with the lower face of an upper wall part 401t. The lower end part of the dielectric plate 420 lies in a gap between the first and second electrodes 450A and 450B and electrically separates the first and second electrodes 450A and 450B.

On both faces of the dielectric plate 420, first and second conductors 430A and 430B made of a copper-nickel plated metal film, for example, are formed so as to extend in the longitudinal direction A. The upper ends of the conductors 430A and 430B in the height direction H are positioned away from the lower face of the upper wall part 401t, and the lower end parts of the conductors 430A and 430B are connected to the first and second electrodes 450A and 450B, respectively.

The coaxial tube 225 is connected to an approximately center position in the longitudinal direction A of the waveguide WG. As shown in FIG. 6, an outer conductor 225b passes through a hole formed in the upper wall part 401t and is electrically connected to the first conductor 430A via a connection member 431, and an inner conductor 225a passes through a hole formed in the upper wall part 401t and is electrically connected to the second conductor 430B.

Here, it is necessary to apply a high-frequency electric field between the first and second conductors 430A and 430B in a balanced manner relative to a ground. On the other hand, the high-frequency power source and an output section of the matching box are generally an imbalanced line such as a coaxial line. Therefore, it is necessary to provide a balance-imbalance converter between the high-frequency power source and a waveguide 400. Examples of the balance-imbalance converter include a Sperrtopf type. That is, as shown in FIG. 6, a metal tube 250 having a length equal to a quarter of the wavelength λ of a free space (5 m at 60 MHz) is provided outside of the coaxial tube 225. An upper end part 250e1 of the metal tube 250 is connected to the outer conductor 225b. The metal tube 250 and the outer conductor 225b form a distributed parameter line. In the distributed parameter line in which one end having a length equal to a quarter of the wavelength λ has been shorted, it seems that impedance takes an infinite value when viewed from the other end. Accordingly, the impedance between the outer conductor 225b as viewed from the lower end and the ground becomes significantly large, and power is supplied in a balanced manner with a high frequency wave.

In the plasma generation mechanism 400 according to the present embodiment, it is possible to set the height h of the waveguide WG to 165 mm. Thus, the height h of the waveguide WG can be significantly reduced as compared to that in the basic-type plasma generation mechanism 200. As a result, it is possible to reduce the production costs of the plasma processing apparatus and downsize the plasma processing apparatus.

### Second Embodiment

FIG. 7 is a perspective cross-sectional view showing a plasma generation mechanism 500 according to a second embodiment. Here, the plasma generation mechanism 500 according to the present embodiment corresponds to each of the two plasma generation mechanisms 200 shown in FIG. 1 and FIG. 4. That is, the plasma generation apparatus according to the present embodiment replaces the two plasma generation mechanisms 200 shown in FIG. 1 and FIG. 4 with the plasma generation mechanism 500 of FIG. 7. In the plasma processing apparatus according to the present embodiment, there is provided an adjustment mechanism for causing the waveguide to be always in the cut-off state even when a load is changed, that is, the above-described two impedance variable circuits 380 and two coaxial tubes 385 respectively connecting the two impedance variable circuits 380. Further, the plasma generation mechanism 500 shown in FIG. 7 is substantially equal to the above-described plasma processing mechanism 200 and has the same functions.

The plasma processing mechanism 500 has a waveguide member 501. The waveguide member 501 is formed of conductive material such as an aluminum alloy, in a tubular shape in the longitudinal direction A, and defines the waveguide WG having a rectangular cross section in a direction crossing the longitudinal direction A. More specifically, the waveguide 501 has an upper wall part 501t, and side wall parts 501w1 and 501w2 which extend downward from end parts of the upper wall part 501t in the width direction B.

Below the waveguide member 501, there are provided first and second electrodes 550A and 550B. The first and second electrodes 550A and 550B are plate members made of conductive material such as an aluminum alloy, have a rectangular shape, and extend in the longitudinal direction A. The first electrode 550A is disposed so as to face the plasma formation space PS and to be vertical to the side wall part 501w1, extends in the longitudinal direction A, and is electrically connected to the lower end part of the side wall part 501w1. The second electrode 550B in juxtaposed with the first electrode 550A with a predetermined gap, disposed so as to face the plasma formation space PS and to be vertical to the side wall part 501w2, and electrically connected to the lower end part of the side wall part 501w2.

In the waveguide WG, there is provided a dielectric plate 520 formed of dielectric material such as aluminum oxide. The dielectric place 520 has a rectangular shape and extends in the longitudinal direction A. The dielectric plate 520 is in contact with one side wall part 501w2 and the upper end part of the dielectric plate 520 in the height direction H is in contact with the lower face of the upper wall part 501t. The lower end part of the dielectric plate 520 lies in a gap between the first and second electrodes 550A and 550B and electrically separates the first and second electrodes 550A and 550B.

One the side of a side wall part 501w1 of the dielectric plate 520, there is provided a conductor 530 made of a plate member formed of conductive material such as an aluminum alloy so as to be in contact with the dielectric plate 520. The conductor 530 extends in the longitudinal direction A, and the upper end part of the conductor 530 is positioned away from the lower face of the upper wall part 501T and the lower end part of the conductor 530 is positioned on the first electrode 550A so that the conductor 530 is electrically connected to the first electrode 550A.

The coaxial tube 225 is disposed in the height direction H and bent at a right angle in the middle so that an outer conductor 225b2 extending in the width direction B is connected to the side wall part 501w2, and the inner conductor 225a2 extending in the width direction B passes through the dielectric plate 520 and is connected to the conductor 530. Note that the coaxial tube 225 may also be connected to the upper part of the waveguide WG, that is, to the side of the upper wall part 501t.

In the plasma generation mechanism 500 according to the present embodiment, it is possible to set the height h of the waveguide WG to about 190 mm. Thus, the height h of the waveguide WG can be reduced by about half as compared to that in the basic-type plasmid generation mechanism 200. As a result, it is possible to reduce the production costs of the plasma processing apparatus and downsize the plasma processing apparatus.

In the first and second embodiments, a description has been given of the case where a hollow is formed in the waveguide. However, the present invention is not limited to this, and it is also possible to fill the hollow in the waveguide with a dielectric.

In the first and second embodiments, a conductor is disposed so as to be in contact with the dielectric plates 420 and 520 provided in the waveguide. However, the present invention is not limited to this, and it is also possible to dispose the conductor away from the dielectric plates 420 and 520 when plasma is not generated in the vicinity of the dielectric plates 420 and 520.

In the first and second embodiments, the power supply position is the center position in the longitudinal direction of the waveguide. However, the power supply position is not limited to this, and can be changed as needed.

Although the embodiments of the present invention have been explained above in detail with reference to the attached drawings, the present invention is not limited to such examples. obviously, those having ordinary knowledge in the technical field to which the present invention belongs can conceive various kinds of variation and modification within the range of the technical idea which is specified in claims, and it is to be understood that also these variations and modifications naturally belong to the technical scope of the present invention.

### REFERENCE SIGNS LIST

225 Coaxial tube
400, 500 Plasma generation mechanism
401, 501 Waveguide member
420, 520 Dielectric plate
430A, 430B Conductor
530 Metal plate
450A, 450B, 560A, 560B Electrode
PS Plasma formation space
WG Waveguide

1. A plasma processing apparatus comprising:
a waveguide member configured to define a waveguide having a rectangular cross section in a direction crossing a longitudinal direction;
first and second electrodes for electric field formation disposed so as to face a plasma formation space, defining the waveguide in cooperation with the waveguide member, and electrically connected to the waveguide member;
a transmission path configured to supply electromagnetic energy from a predetermined power supply position in the longitudinal direction into the waveguide;
a dielectric plate disposed in the waveguide and extending in the longitudinal direction; and
at least one conductor disposed, in the waveguide, on at least one side of the waveguide in a width direction with respect to the dielectric plate, extending along the dielectric plate, and electrically connected to one of the first and second electrodes.

2. The plasma processing apparatus according to claim 1, wherein the at least one conductor includes a metal film formed on a surface of the dielectric plate.

3. The plasma processing apparatus according to claim 1, wherein the at least one conductor includes a metal plate disposed separately from the dielectric.

4. The plasma processing apparatus according to claim 1, wherein part of the dielectric plate is disposed between the first and second electrodes and electrically separates the first and second electrodes.

5. The plasma processing apparatus according to claim 1, wherein
the transmission path includes a coaxial tube,
the at least one conductor includes first and second conductors disposed on both sides of the dielectric plate and electrically connected to the first and second electrodes, and
an inner conductor of the coaxial tube is connected to one of first and second conductors at a predetermined position in the longitudinal direction, and an outer conductor of the coaxial tube is connected to the other of the first and second conductors at a predetermined position in the longitudinal direction.

6. The plasma processing apparatus according to claim 5, further comprising:
a metal tube having a predetermined length to which part of the coaxial tube is inserted, wherein
the metal tube is connected to a reference potential, and one end part is connected to the waveguide member, while the other end part is connected to the outer conductor of the coaxial tube.

7. The plasma processing apparatus according to claim 6, wherein
the transmission path includes a coaxial tube,
the at least one conductor is provided only on one side of the dielectric
plate, and
the outer conductor of the coaxial tube is connected to the waveguide member, and the inner conductor of the coaxial tube passes through the dielectric plate and is connected to the at least one conductor.

8. The plasma processing apparatus according to claim 1, wherein the waveguide is configured so as to cause a high frequency wave to resonate, the high frequency wave being supplied from the transmission path and having a predetermined plasma excitation frequency.

9. A plasma processing method comprising the steps of:
disposing an object to be processed at a position facing a plasma formation space in a container having a plasma generation mechanism provided therein, the plasma generation mechanism comprising the plasma processing apparatus according to claim 1; and
performing plasma processing on the object to be processed with plasma excited by the plasma generation mechanism.
